(19) United States
(12) Patent Application Publication
(10) Pub. No.: US 2007/0046964 A1
(43) Pub. Date: Mar. 1, 2007

(54) Method for mapping of color values of one color image to the color values of a highlight color image with at least two highlight color colors, as well as corresponding printing system

(76) Inventors: Helmut Weiner, Munchen (DE); Rudiger Siemens, Munchen (DE)

Correspondence Address: SCHIFF HARDIN, LLP;PATENT DEPARTMENT, 6600 SEARS TOWER, CHICAGO, IL, 60606-6473, US

(21) Appl. No.: 11/504,470

(22) Filed: Aug. 15, 2006

(30) Foreign Application Priority Data
Aug. 25, 2005 (DE) 10 2005 040 339.5

(51) Int. Cl. G03F 3/08

(52) U.S. Cl. 358/1.9; 358/518

(57) ABSTRACT

In a method and printing system for mapping of color values of a color image to color values of a highlight color image with two highlight color colors, a mapping rule is developed such that a range in which a color value of the color image can be mapped to both highlight color colors is limited to a range between the two highlight color colors. Also, mapping rules for mapping of the color values to one of the two highlight color colors are designed such that they produce only a small portion of the highlight color color to be mapped in a neighborhood of the respective highlight color color that is not to be mapped. A color impression caused by highlight color colors of the color image is thus retained. Additionally a darkening of the color image via an application of too much toner of both highlight color colors is avoided.

### BACKGROUND

A preferred embodiment relates to a method for mapping color values of one color image to the color values of a highlight color image with at least two highlight color colors (2HC image).

A method for mapping of color values of one color image to the color values of a highlight color image that comprises only color values of a highlight color color space is described in U.S. Pat. No. 5,237,517. Such a highlight color color space comprises all color values in the range between the greyscales and a predetermined highlight color color. This method is also described in “Principles for mapping from full color to highlight-color”, Steven J. Herrington, in IS&T's Eighth International Congress on Advances in Non-Impact Printing Technologies (1992), page 458 and the following.

A method for mapping of color values of one color image to the color values of a highlight color image arises from WO 01/78374 A1, in which the color values (shown in the RGB color space) of the color image to be mapped are mapped by means of a mapping step to the highlight color space that corresponds to a projection of the color values onto the high color color. The corresponding calculations occur in the RGB color space. A conversion into a different color space is not necessary. Diverse corrections are additionally provided so that a highlight color image is generated that is optimally true to nature for the human eye.

A method with which an HC image is generated from a color image for printing on a digital printer arises from WO 01/63909 A1 or United States Patent Application 2003/123070 A1.

Digital printers can normally print colors only in two color saturation degrees (no color or full color saturation) or only in a very few color saturation levels. In conventional methods a template print image for the standard color and a template print image for the HCL color are therefore transformed with a dither method into a rastered image that is described by means of half-tone values.

In contrast to this, in the method known from WO 01/63909 A1 half-tone printing reference patterns are used for generation of print values for a print template image for a standard color and for a print template image for an HC color. The information of which color values of the template image are associated with a standard color range or an HC color range is integrated into the half-tone printing reference pattern, whereby the method for printing of an HC image can be limited to the selection of the corresponding half-tone printing reference pattern and the adoption of the print value specified in the half-tone printing reference pattern. A corresponding selection for determination of the print values for the standard color and for the HC color is merely to be implemented for each image point.

From U.S. Pat. No. 6,185,013 B1 a method is known with which a color image is mapped to a highlight color image with two highlight color colors (2HC image). Two different methods are hereby disclosed, depending on whether a photographic image or a presentation graphic should be transformed into the 2HC image. Given a presentation graphic, colors should be kept in a highlight color tone before and after the mapping, the relative brightness and saturation of a color tone should be retained, non-neutral colors should be mapped to non-neutral colors and fully-saturated colors should be mapped to a predetermined set.

Given photographic images, primarily the luminance should be retained. This is achieved in that the mapping to the individual highlight color colors initially occurs precisely as in the method known from U.S. Pat. No. 5,237,517, whereby, however, the white content is increased or the black content is reduced to adjust the luminance.

### SUMMARY

It is an object to achieve a method and a printing system for mapping of color values of a color image to the color values of a highlight color image with at least two highlight color colors (2HC image), in which the photographic impression of an image and the color association is to be retained with a single mapping rule insofar as this is possible with a 2HC image.

In a method or system for mapping a color value of a color image to a color value of a highlight color image with at least two highlight color colors, the color values respectively exhibiting a color content in a black content, color values that are not arranged in an intermediate range between the two highlight color colors are mapped to black or to the highlight color color of the two highlight color colors that is adjacent to the color value to be mapped. The color value that is arranged in the intermediate range between the two highlight color colors as mapped to one of the two highlight color colors, one color content being mapped to a color saturation level of the respective highlight color color, and wherein rules of the two mappings from a function monotonously steadily falling from the highlight color color to be mapped, beginning at a direction towards the highlight color color that is not be mapped, the function assuming a value “0” at the respective highlight color color that is not to be mapped. The function is formed such that the function runs below a line in a neighboring range of the highlight color color that is not to be mapped, the line running in a direction of the highlight color color that is not to be mapped and ends there at a value “0”.

### BRIEF DESCRIPTION OF THE DRAWINGS

FIG. 1 is a cube for representation of the RGB color space with the colors w=white, k=black, r=red, g=green, b=blue, c=cyan, m=magenta, y=yellow;

FIG. 2 shows in a coordinate system, the mapping factors p′ for the highlight color colors yellow and light green, dependent on the color values of colors to be mapped according to a known mapping rule;

FIG. 3 shows in a coordinate system, the mapping factors p′ for the highlight color colors yellow and light green, dependent on the color values of colors to be mapped according to the mapping rule of the preferred embodiment;

FIG. 4 illustrates a projected color plane of the RGB color space that is orthogonal to the grey line; and

FIG. 5 is a printing system in a schematic representation.

### DESCRIPTION OF A PREFERRED EMBODIMENT

For the purposes of promoting an understanding of the principles of the invention, reference will now be made to a preferred embodiment illustrated in the drawings and specific language will be used to describe the same. It will nevertheless be understood that no limitation of the scope of the invention is thereby intended, such alterations and further modifications in the illustrated device, and/or method, and such further applications of the principles of the invention as illustrated therein being contemplated as would normally occur now or in the future to one skilled in the art to which the invention relates.

In the method of a preferred embodiment, color values of a color image are mapped to color values of a highlight color image with at least two highlight color colors. The color values respectively exhibit a color content and a black content, whereby: color values that are not arranged in the intermediate range between the two highlight color colors are mapped to black (according to known mapping rules (p′) for mapping of a color image to a highlight color image with a single highlight color color) or to the highlight color color of the two highlight color colors that is close to the color value to be mapped; and a color value that is arranged in the intermediate range between the two highlight color colors is mapped (by means of two mapping rules (p*) for mapping of the color content of the color value) to one of the two highlight color colors; in which method respectively one color content is mapped to a color saturation level of the respective highlight color color (F_{HC1}, F_{HC2}); whereby the two mapping rules (p*) form a function monotonously, steadily falling from the highlight color color to be mapped, beginning in the direction towards the highlight color color that is not to be mapped; which functions assume the value “0” at the respective highlight color color not to be mapped and are formed such that the function runs below a straight line in a neighboring range of the highlight color color that is not to be mapped, which straight line runs (beginning at the maximum saturation of the highlight color color to be mapped) in the direction of the highlight color color that is not to be mapped and ends there at the value “0”.

Since a color value of the color image can only be mapped to both highlight color colors when it is located in the intermediate range between both highlight color colors, and in that the mapping to the other highlight color color is additionally limited in the neighboring range of a specific highlight color color, a distortion of the color impression of the respective highlight color colors is prevented. With the mapping rule of a preferred embodiment it is additionally ensured that an image point is not excessively darkened by the superimposition of the color contents of both highlight color colors and a corresponding black content. The highlight color image with two highlight color colors thus effects a photographic impression or a representation of the original color image that is true to nature insofar as this is possible with the color space of a 2HC image.

The neighboring range is advantageously between 20% and 70% of the range of the intermediate range between the two highlight color colors that abuts the highlight color color that is not to be mapped.

According to a preferred embodiment, the sum of the color saturation levels determined for each color content is not more than the maximum color saturation level of an individual color.

The method of a preferred embodiment is appropriately only applied when the intermediate range between the two highlight color colors not greater than the range between the maximum and the first zero point of the known mapping rule (p′) that is adjacent to said maximum.

Given use of a plurality of highlight color colors (such as, for example, three, four, five, six, seven or even more highlight color colors) the intermediate range between two adjacent highlight color colors respectively forms an overlap range in which the input color can be mapped to one or both adjacent highlight color colors.

An exemplary preferred embodiment is a development of the method known from WO 01/78374 A1 for mapping of color values of a color image to the color values of a highlight color image with a single highlight color color (1 HC image). In this method for mapping of color values of one color image, the color values of the color image are represented as vectors of the RGB color space. In the present specification of the preferred embodiment, vectors are represented by capital letters and scalars are represented by lowercase letters. The color black is represented by the vector (0, 0, 0) and the color white is represented by the vector (255, 255, 255). The color values of the color image to be mapped are respectively represented by a vector Cᵢₙ with (rᵢₙ, gᵢₙ, bᵢₙ)

The following notations known from vector mathematics are used in the specification of the preferred embodiment. With the scalar product or vector product, two color values c₁=(r₁, g₁, b₁), c₂=(r₂, g₂, b₂) are multiplied with one another according to the following formula:
C₁·C₂:=r₁·r₂+g₁·g₂+b₁·b₂

The norm of a vector is calculated according to the following formula:
|C₁|:=\sqrt{r₁²+g₁²+b₁²}

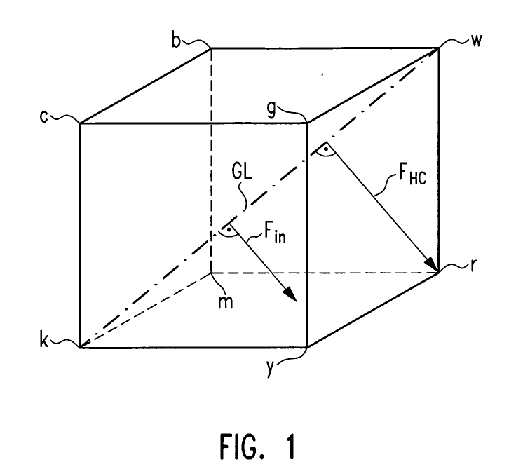

In FIG. 1 the RGB space is represented by a cube, where by the edges of the cube are associated with the colors k=black, y=yellow, r=red, m=magenta, w=white, b=blue, c=cyan and g=green. The diagonal line GL from black to white comprises all grey values of the RGB color space. This diagonal is therefore subsequently designated as a grey line GL. For the following explanations of the preferred embodiment the unit vector pointing from black to white along the grey line GL is important, which unit vector is represented according to the following
E_{Diag}:=(1/\sqrt{3;}1/\sqrt{3})

The black content kᵢₙ of the color value Cᵢₙ is defined according to the following:
kᵢₙ=E_{Diag}·Cᵢₙ=(rᵢₙgᵢₙbᵢₙ)/\sqrt{3}

Since, in the present exemplary embodiment, black is represented by (0, 0, 0) and white is represented by (255, 255, 255), the black content kᵢₙ has a value range from 0 to 255, whereby 0 represents the maximum black content and 255 represents the minimum.

The black content vector Kᵢₙ of the color Cᵢₙ is consequently:
Kᵢₙ=kᵢₙ·E_{Diag}

A color content vector can consequently also be calculated from the color value according to the following formula:
Fᵢₙ=Cᵢₙ−kᵢₙ·E_{Diag}

The color content vector of the highlight color color can also be represented in a corresponding manner:
F_{HC}=C_{HC}−k_{HC}·E_{Diag}

In FIG. 1 the color content vector F_{HC} of the highlight color color red is plotted with C_{HC}=(255, 0, 0). The color content vector is orthogonal to the grey line GL. The same correspondingly applies for the color content vector Fᵢₙ of an arbitrary color value.

Since the color content vectors are orthogonal to the grey line, they lie in the plane orthogonal to the grey line that can be designated as a color plane since the vectors comprised therein are independent of the grey content. A mapping to the highlight color color (which mapping is described in detail below) can be executed in this color plane without a coordinate transformation being necessary, as it is applied in the method described above (transformation in YES).

A mapping factor p′ can be calculated from the color content vectors Fᵢₙ of a color value to be mapped and the highlight color color according to the following formula:
p′(C_{HC}, Cᵢₙ)=cos³(F_{HC}, Fᵢₙ)
in the event that cos(F_{HC}, Fᵢₙ)>0; otherwise P′(C_{HC}, Cᵢₙ)=0 applies.

The cosine function between the two color vectors F_{HC}, Fᵢₙ in Euclidean vector space is determined by the following vector product:

$$cos ( {F}_{HC} , {F}_{i n} ) = \frac{{F}_{HC} \cdot {FC}_{i n}}{\vert {F}_{HC} \vert \cdot \vert {F}_{i n} \vert}$$

The color content vector Fᵢₙ mapped to the color content vector F_{HC} Of the highlight color color is calculated with the mapping factor p′ according to the following:
C″_{Gamut}=|Fᵢₙ|p′(C_{HC}, Cᵢₙ)·F_{HC}/|F_{HC}|

In this formula F_{HC}/|F_{HC}| represents the unit vector E_{HC} that is directed in the direction of the highlight color color. The mapped vector C″_{Gamut} thus possesses the direction of the highlight color color in RGB color space with the magnitude of the color content vector Fᵢₙ of the color value to be mapped that is multiplied with the mapping factor p′.

The black content of the color value to be mapped is still not taken into account in this mapping. The above mapping vector can therefore be expanded according to the following:
C′_{Gamut}=|Fᵢₙ|p′(C_{HC}, Cᵢₙ)·F_{HC1}/|F_{HC1}|+kᵢₙE_{Diag}

With this correction the black content is adopted unchanged into the highlight color color space since it should also be represented unchanged (relative to the output image) in a highlight color image.

With the above mapping the original black content is thus adopted unchanged and the original color content is mapped to the highlight color color. Given the calculation of C″_{Gamut}, the color contents of Fᵢₙ that are either contrary or orthogonal to the color content vector F_{HC} of the highlight color color are omitted. The omitted color content can be represented by C″_{Gamut} minus Fᵢₙ or C′_{Gamut} minus Cᵢₙ. Given digital electrophotographic printing a grey value shift can occur via the dithering. This can be accounted for via an empirical color correction vector K_{cor} according to the following formula:
C_{Gamut}=C′_{Gamut}+((C′_{Gamut}−Cᵢₙ)·K_{cor})E_{Diag}
The color correction value possesses the following values: (−0.12; −0.27; −0.03).

The above mapping associates exactly one color value of the highlight color color space with each color value of a color image. Highlight color images that are very natural to the human eye can be generated with this mapping. A color monitor can be directly activated with the mapped color value C_{Gamut} since this color value is a color value of the RGB color space.

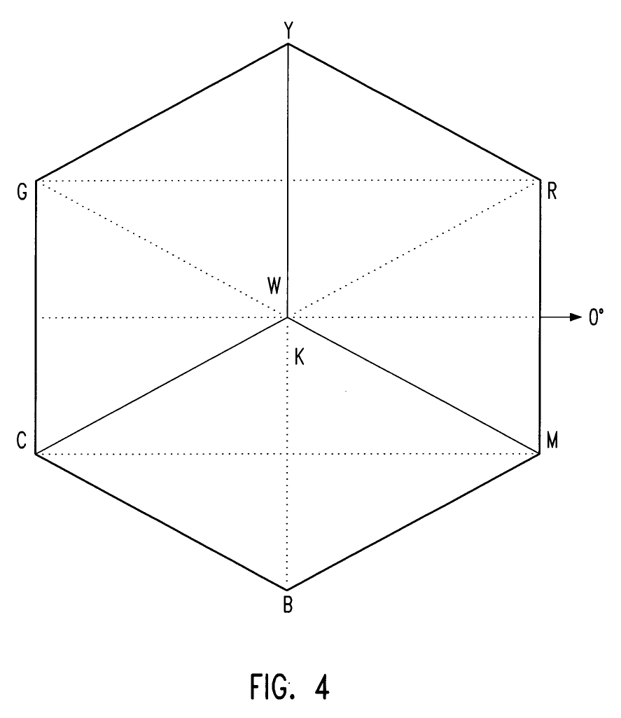

The mapping factor p′ is subsequently examined in detail. It is hereby appropriate to project the RGB color space onto a plane, the color plane, that is orthogonal to the grey line GL. This color plane is shown in FIG. 4. It forms a regular hexagon with the vertices red (R), yellow (Y), green (G), cyan (C), blue (B) and magenta (M). The 0° line is located in the middle between the colors magenta and red. The color yellow (Y) is located at 90° and the color light green (G) is located at 120°. The direction from the middle outwards represents the color saturation. There is no color saturation at all in the middle. The individual colors exhibit maximum color saturation at the boundary lines.

In the color plane the individual color values F can be represented by polar coordinates, i.e. by an angle α and its magnitude |F|. Primarily the angle α of the color values is taken into account in the determination of the mapping factor p* according to the preferred embodiment.

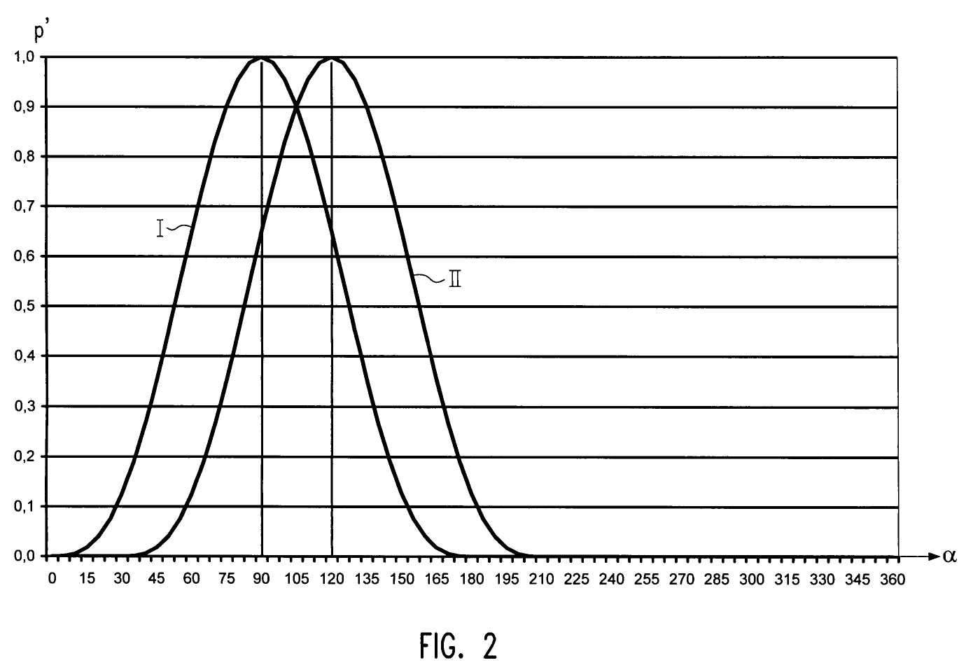

In FIG. 2 the curve of the mapping factor p′ for the highlight color color yellow is shown with I. p′ of the highlight color color yellow has its maximum of 1 at 90° and symmetrically decreases until 0 at 0° or 180°.

The curve of p′ for the color light green is designated with II in FIG. 2. The maximum thus lies at 1200 and the decrease to 0 is reached at 30° or 210°. The function of p′ for the highlight color color light green is thus displaced by 30° relative to the function p′ of the highlight color color yellow.

If one uses both of these mapping rules in order to generate a highlight color image with the two highlight color colors yellow (90°) and light green (120°), colors whose color values lie in the range between 30° and 180° are mapped to both highlight color colors. Such a mapping would mean that both a black content and color contents for both highlight color colors would be printed at a corresponding image point. This causes the following problems:
Although the highlight color image possesses two highlight color colors, colors of the color image to be mapped that correspond to the highlight color colors or are very similar to these would be strongly distorted by the respective further highlight color color. For example, image points that are exactly yellow in the original color image are represented in the mapped highlight color image by a mixture of yellow with a high proportion of green. The original yellow color impression would hereby be adulterated although it would in principle be capable of representation with the present highlight color color space.
The image point is darkened due to the superimposition of the black content of a color content of the first highlight color color and of a color content of the second highlight color color, meaning that the resulting black content is significantly increased. This problem was already recognized in U.S. Pat. No. 6,185,013 B1, whereby to solve this problem it is proposed to increase the white content or to reduce the black content. The brightness of the individual image points can in fact herewith be compensated within certain limits. However, this method does not work in images to be printed when they exhibit image points in which the black content is already very low.

The color distortion explained above is also not counteracted with this method known from U.S. Pat. No. 6,185,013 B1.

To remedy these problems it is proposed according to the preferred embodiment to calculate the mapping factor p* (instead of the mapping factor p′) for the mapping of an initial color value Fᵢₙ with the polar coordinate αᵢₙ to one of the two highlight color colors F_{HC1} or F_{HC2} according to the following formula:
p*(C_{HC1/HC2}, Cᵢₙ)=cos³(F_{HC1/HC2}, F*ᵢₙ)=cos³(α_{HC1/HC2}, α*)
for
F_{HC1}≦Fᵢₙ≦F_{HC2} or, respectively, α_{HC1}≦αᵢₙ≦α_{HC2},
whereby

$${α}^{*} = {α}_{HCI} + \frac{\vert {α}_{HCII} - {α}_{HCI} \vert}{Δ} \cdot ( {α}_{i n} - {α}_{HCI} ) ,$$

whereby: F_{HCI} is the highlight color color to which the input color value Fᵢₙ is mapped and α_{HCI} is its corresponding polar coordinate; F_{HCII} is the respective other highlight color color of the two highlight color colors F_{HC1}, F_{HC2}; Δ is the difference of the color value at which the previous mapping factor p′ assumes the value “0” (=180° for yellow) minus the color value of the corresponding highlight color color (=90° for yellow). Δ thus represents the value range starting from the respective highlight color color until the value “0” of p′. In the present exemplary embodiment:
Δ=90°.

The mapping factor p* applies only for the range between the two highlight color colors F_{HC1} and F_{HC2} in which a color is mapped to both highlight color colors. In other words, this means that the application range of the mapping factor p* is limited solely to the range that lies between the two highlight color colors F_{HC1} and F_{HC2}, assuming that the interval between the two highlight color colors F_{HC1} and F_{HC2} is not greater than A, meaning that:
|α_{HCII}−α_{HCI}|<Δ

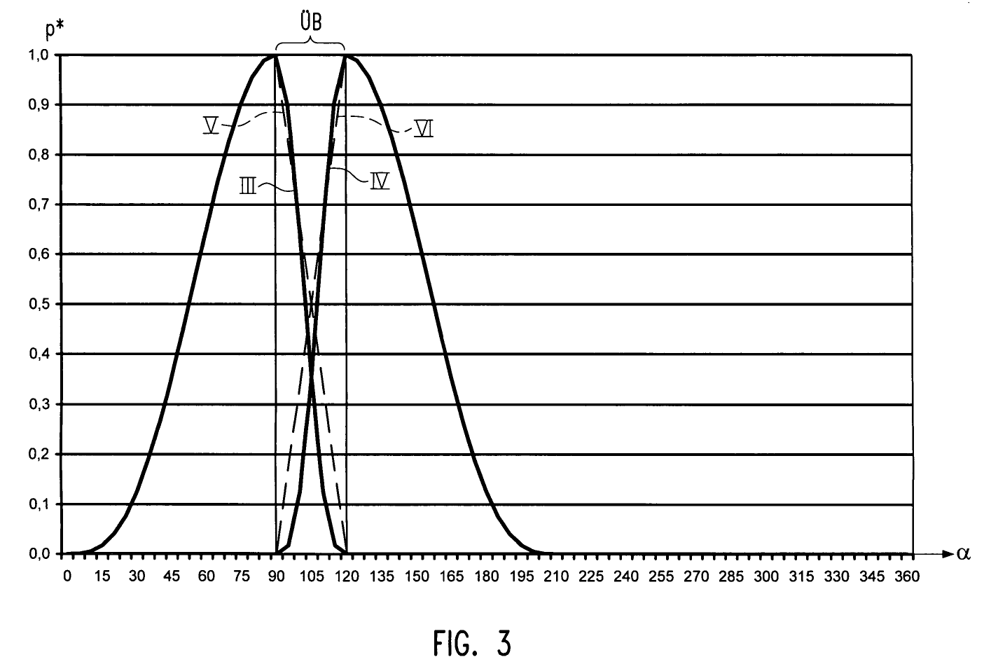

If there is no such range, the mapping rule according to the mapping factor p* does not apply. This range is designated as an overlap range (ÜB in FIG. 3) since, given the mapping rule of the preferred embodiment for the mapping factor p*, the functions of both mapping factors p* of both highlight color colors F_{HC1} and F_{HC2} overlap only in this range, such that the problems explained above occur. Outside of this overlap range the input color values Fᵢₙ are mapped to the closest highlight color color with the conventional mapping factor p′. This is well-recognizable in FIG. 3.

The input angles αᵢₙ of the input color values Fᵢₙ are mapped to the entire value range Δ of the original function of the mapping factor p′ with α*. In other words, this means that the function of the original mapping factor p′ is compressed together via usage of p* on the overlap range ÜB. The function curve of p* hereby resulting is designated in FIG. 3 with III for the highlight color color yellow and with IV for the highlight color color light green.

For clarification, it is again noted that, with the method of the preferred embodiment, the mapping rule is to be executed in the overlap range ÜB both for the first highlight color color (p*(C_{HC1}, Cᵢₙ)) and for the second highlight color color (p*(C_{HC2}, Cᵢₙ)). This means that, in the formula described above for calculation of C_{Gamut}, the value for C′_{Gamut} is calculated according to the following formula:
C′_{Gamut}=|Fᵢₙ|p*(C_{HC1}, Cᵢₙ)·F_{HC1}/|F_{HC1}|+|Fᵢₙ|p*(C_{HC2}, Cᵢₙ)·F_{HC2}/|F_{HC2}/|F_{HC2}+kᵢₙE_{Diag}

As is clear from this formula, the black content of the input color Cᵢₙ is adopted unchanged.

Instead of the unchanged adoption of the black content, it can also be appropriate to reduce the black content KᵢₙE_{Diag} by one of the two color saturation levels of the two highlight color colors, in particular by the value of both color saturation values of both highlight color colors.

In business graphics it can also be appropriate to determine the black content independent of the black content of the input color Cᵢₙ, solely from the determined color saturation values of both highlight color colors:

$${K}_{outHC 1} = Y - max ( {R}_{GamutHC 1} , {G}_{GamutHC 1} , {B}_{Gamut HC 1} ) - {C}_{GamutHC 1}^{′′} \cdot \frac{\vert {F}_{HC 1} \vert}{\vert {F}_{HC 1} \vert} , \\ {K}_{outHC 2} = Y - max ( {R}_{GamutHC 2} , {G}_{GamutHC 2} , {B}_{Gamut HC 2} ) - {C}_{GamutHC 2}^{′′} \cdot \frac{\vert {F}_{HC 2} \vert}{\vert {F}_{HC 2} \vert} ,$$

whereby Y is the value for the maximum color saturation that is typically 1 or 255 depending on the scaling. The black content K_{2HC} that is adopted in the 2HC image is the smaller of the two black contents K_{outHC1} or K_{outHC2} calculated above.

With this correction it is avoided that the 2HC image is excessively darkened.

A further appropriate, alternative method for determination of the black content K_{2HC} is the subtraction of both color saturation values of both highlight color colors from the maximum possible color saturation level Y:
K_{2HC}=Y−C″_{GamutHC1}·E_{HC1}−C″_{GamutHC2}·E_{HC2}

Via the usage of p* it is ensured that colors that, in the color image to be mapped, are similar to one of the two highlight color colors are mapped to a similar color. Via the compression of the mapping functions or mapping rule to the overlap range it is also ensured that the individual color contents are not too large and the image points generated herewith are not too dark.

The invention is naturally not limited to the present exemplary preferred embodiment. It is appropriate that, given a mapping of a color value to both highlight color colors, it is ensured that the sum of both corresponding mapping factors p* of a specific color value is not greater than 1. Since these mapping factors are proportional to the color saturation values, it is ensured that the sum of the color saturation values also does not exceed the magnitude of 1.

It is also appropriate to design the mapping rule or mapping function of the mapping factors p* such that they monotonously decrease in the direction towards other highlight color colors, whereby, at least in the neighboring range of the other highlight color color, they lie below the connection line between the value 0 at the other highlight color color and the maximum saturation at the highlight color color to which they are mapped. In FIG. 3 the corresponding connection line is designated with V for the highlight color color yellow and with VI for the highlight color color light green. The neighboring range advantageously comprises a range from 20% to 70% of the overlap range abutting the other highlight color color that is not to be mapped.

With all of the conditions specified above that can be applied individually or in combination, it is ensured that, given the mapping to two highlight color colors, color values of the color image to be mapped that are located in proximity to one of the two highlight color colors are more strongly mapped to the respective highlight color color. These highlight color colors are thus more strongly weighted in the mapping.

The method of the preferred embodiment has been explained above using an exemplary embodiment that uses two highlight color colors. However, the preferred embodiment is not limited to a method with two highlight color colors. In principle arbitrarily many highlight color colors can be used in the framework of the preferred embodiment. In electrophotographic printing, before long first printers will be introduced to the market that print up to five highlight color colors. Printing methods with more than five highlight color colors are also known in offset printing. Given use of a plurality of highlight color colors, the intermediate range between two adjacent highlight color colors respectively forms an overlap range in which the input color can be mapped to one or both adjacent highlight color colors.

The color values of the highlight color color that are determined with the method of the preferred embodiment are dithered in a known manner for digital printing. The method according to WO 01/63909 A1, in which the determination of the color value of the highlight color image and the dithering can be executed in a single step, is particularly advantageous. This known method can be directly transferred to the method of the preferred embodiment, which is why reference is made to the entire content of WO 01/63909 A1.

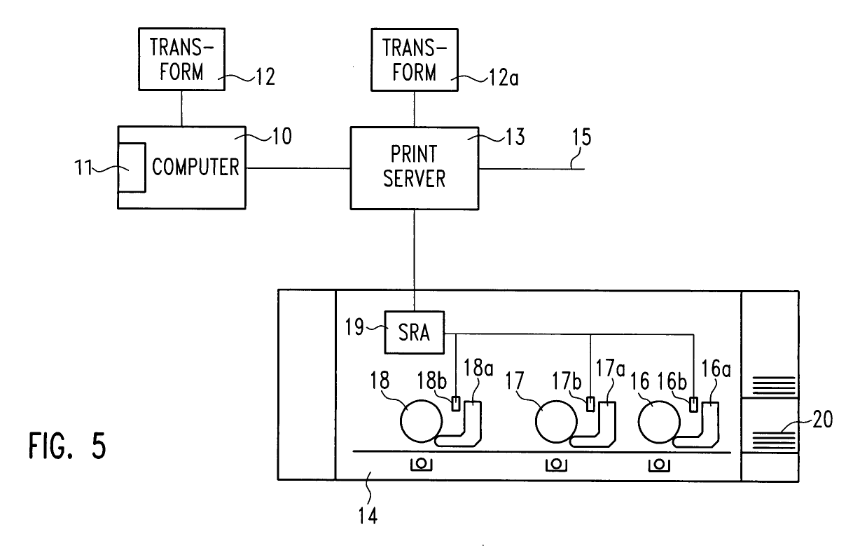

In FIG. 5 a printing system is shown in which color image data related to a full color space (RGB) are generated in a user software program 11 running on a user computer 10. The image data so generated can then be transformed to the 2HC color space with the method of the preferred embodiment described above via a transformation software program 12 or, respectively, via a corresponding electronic circuit (hardware) in the user computer 10. The data so prepared are subsequently transferred to a print server 13 to which a printing apparatus 14 is connected in turn. Further computers can be connected at the print server 13 via the connection 15, from which computers the print server 13 can also receive RGB image data or other full color image data such as yellow-magenta-cyan-black (YMCK) image data that are not optimized for the 2HC color space. The corresponding conversion of such full color image data to 2HC image data can then occur via the transformation software program 12a (which functions just like the transformation program 12) installed in the print server 13.

Three printing stations 16, 17 and 18 that can respectively print in three different colors are located in the printing apparatus 14. For example, for this the electrophotographic printing group 16 comprises a developer station 16a containing black toner, the printing group 17 comprises a developer station 17a containing red toner and the printing group 18 comprises a developer station 18a containing blue toner. Moreover, each of the printing groups 16, 17, 18 comprises known electrophotographic components such a photoconductor drum, corotron devices and an exposure unit (such as, for example, a light-emitting diode comb). The data obtained from the print server are thereby received by a scalable raster architecture (SRA) print data controller 19 comprised in the printing apparatus 14, respectively rastered into individual image points and supplied in true color to the three printing groups 16, 17, 18 or the corresponding light-emitting diode comb 16b, 17b, 18b to form a latent image on the corresponding photoconductor drum. The electrostatic images so dispatched are then electrophotographically developed in a known manner with toner and transfer-printed onto the recording medium, here a single sheet 20 of paper, such that the desired 2HC image is created on the paper sheet 20.

The preferred embodiment can be summarized as follows:

The preferred embodiment concerns a method and printing system for mapping of color values of a color image to the color values of a highlight color image with two highlight color colors.

With the preferred embodiment method a conventional mapping rule for mapping of a color image to a highlight color image with a single highlight color color is developed such that the range in which a color value of the color image can be mapped to both highlight color colors is limited to the range between the two highlight color colors, and additionally the mapping rules for mapping of the color values to respectively one of the two highlight color colors are formed such that, in the neighborhood of the respective highlight color color that is not to be mapped, they produce only a small portion of the highlight color color to be mapped. The color impression caused by highlight color colors of the color image is hereby retained. A darkening of the color image due to an application of too much toner of both highlight color colors is additionally avoided.

While a preferred embodiment has been illustrated and described in detail in the drawings and foregoing description, the same is to be considered as illustrative and not restrictive in character, it being understood that only the preferred embodiment has been shown and described and that all changes and modifications that come within the spirit of the invention both now or in the future are desired to be protected.

We claim as our invention:

1. A method for mapping a color value of a color image to a color value of a highlight color image with at least two highlight color colors, the color values respectively exhibiting a color content and a black content, comprising the steps of:
mapping color values that are not arranged in an intermediate range between the two highlight color colors to black or to the highlight color color of the two highlight color colors that is close to the color value to be mapped;
mapping a color value that is arranged in the intermediate range between the two highlight color colors to one of the two highlight color colors, one color content being mapped to a color saturation level of the respective highlight color color, rules of two mappings forming a function monotonously steadily falling from the highlight color color to be mapped, and beginning in a direction towards the highlight color color that is not to be mapped, the function assuming a value “0” at the respective highlight color color that is not to be mapped; and
forming the function such that the function runs below a line in a neighboring range of the highlight color color that is not to be mapped, the line running in a direction of the highlight color color that is not to be mapped and ending there at the value “0”.

2. A method according to claim 1, wherein the neighboring range is 20% and 70% of the intermediate range abutting the highlight color color that is not to be mapped, said intermediate range lying between the highlight color color that is to be mapped and the highlight color color that is not to be mapped.

3. A method according to claim 2, wherein the neighboring range is at least 50% of the intermediate range.

4. A method according to claim 1 wherein the method is only applied when an interval between the highlight color color that is to be mapped and the highlight color color that is not to be mapped is not greater than an interval between a maximum of the known mapping rule and a closest zero point of this mapping rule.

5. A method according to claim 1 wherein a sum of the color saturation levels determined for each color content is not greater than a maximum color saturation level of an individual color.

6. A method according to claim 1 wherein in the intermediate range between the two highlight color colors, the intermediate range being designated as an overlap range, the two mapping rules are formed via compression of the known mapping rule to the overlap range for the two highlight color colors.

7. A method according to claim 1 wherein given the mapping rules in the intermediate range between the highlight color colors, a mapping factor p* is calculated for each of the two highlight color colors C_{HC1} or C_{HC2}:
p*(C_{HC1/HC2}, Cᵢₙ)=cos³ (F_{HC1/HC2}, F*ᵢₙ)=cos³(α_{HC1/HC2}, α*)
for
α_{HC1}≦αᵢₙ≦α_{HC2},
whereby
$${α}^{*} = {α}_{HCI} + \frac{\vert {α}_{HCII} - {α}_{HCI} \vert}{Δ} \cdot ( {α}_{i n} - {α}_{HCI} ) ,$$
where: C_{HCI} is the highlight color color to which the input color value Cᵢₙ is mapped and α_{HCI} is its corresponding polar coordinate; C_{HCII} is the respective other highlight color color of the two highlight color colors C_{HC1}, C_{HC2}; Δ is a difference of the color value at which the previous mapping factor assumes a value “0” minus the color value of the corresponding highlight color color.

8. A method according to claim 7 wherein the highlight color color C_{Gamut} mapped to the image is calculated according to a following formula:
C_{Gamut}=C′_{Gamut}+((C′_{Gamut}−Cᵢₙ)·K_{cor})E_{Diag},
where
C′_{Gamut}=|Fᵢₙ|p*(C_{HC1}, Cᵢₙ)·F_{HC1}/|F_{HC1}|+|Fᵢₙ|p*(C_{HC2}, Cᵢₙ)·F_{HC2}/|F_{HC2}|−kᵢₙE_{Diag}
applies for C′_{Gamut}.

9. A method according to claim 1 wherein a black content is adopted unchanged given mapping of a color value to both highlight color colors.

10. A method according to claim 1 wherein given mapping of a color value to both highlight color colors, a black content is reduced by a larger of two color saturation levels of the two highlight color colors.

11. A method according to claim 1 wherein given mapping of a color value to both highlight color colors, a black content is calculated via subtraction of both color saturation levels of both highlight color colors from a maximum possible color saturation level.

12. A computer program product for mapping a color value of a color image to a color value of a highlight color image with at least two highlight color colors, the computer program product performing the steps of:
mapping color values that are not arranged in an intermediate range between the two highlight color colors to black or to the highlight color color of the two highlight color colors that is close to the color value to be mapped;
mapping a color value that is arranged in the intermediate range between the two highlight color colors to one of the two highlight color colors, one color content being mapped to a color saturation level of the respective highlight color color, rules of two mappings forming a function monotonously steadily falling from the highlight color color to be mapped, and beginning in a direction towards the highlight color color that is not to be mapped, the function assuming a value “0” at the respective highlight color color that is not to be mapped; and
forming the function such that the function runs below a line in a neighboring range of the highlight color color that is not to be mapped, the line running in a direction of the highlight color color that is not to be mapped and ending there at the value “0”.
